(19) United States
(12) Patent Application Publication
(10) Pub. No.: US 2022/0243326 A1
(43) Pub. Date: Aug. 4, 2022

(54) APPARATUS AND METHOD FOR THIN FILM DEPOSITION

(71) Applicants: Kevin P MUSSELMAN, Waterloo (CA); Chee Hau TEOH, Waterloo (CA); Jhi Yong LOHE, Waterloo (CA); Manfred KAO, Sparls, NV (US)

(72) Inventors: Kevin P MUSSELMAN, Waterloo (CA); Chee Hau TEOH, Waterloo (CA); Jhi Yong LOHE, Waterloo (CA); Manfred KAO, Sparls, NV (US)

(21) Appl. No.: 17/621,864

(22) PCT Filed: Dec. 18, 2020
(86) PCT No.: PCT/CA2020/051748

§ 371 Date: Dec. 22, 2021

Related U.S. Application Data
(60) Provisional application No. 62/949,798, filed on Dec. 18, 2019.

(51) Int. Cl. C23C 16/458; C23C 16/455; B01J 19/26; C23C 16/54

(52) U.S. Cl. CPC C23C 16/4586; C23C 16/545; B01J 19/26; C23C 16/455

(57) ABSTRACT

A thin film deposition system including a modular reactor head, a substrate stage and a modular reactor head positioning system. The modular reactor head positioning positions the modular reactor head with respect to the substrate to deliver precursor gases to a substrate located on the substrate stage. The modular reactor head includes a set of modular components that perform different functionalities and may be placed in different configurations.

### CROSS-REFERENCE TO OTHER APPLICATIONS

The disclosure claims priority from U.S. Provisional Application No. 62/949,798 filed Dec. 18, 2019, which is hereby incorporated by reference.

### FIELD OF THE INVENTION

The present disclosure relates generally to thin film deposition and, more specifically to an apparatus and method for thin film deposition.

### BACKGROUND

Techniques such as sputtering, evaporation, and chemical vapor deposition are used to deposit films for many applications (e.g. modern electronics, optical components, display technologies, food packaging, etc.). For these applications, improved control over the film thickness is needed. Atomic layer deposition (ALD) is the best technique for producing films with nanometre-scale thickness control, as it deposits a film one atomic layer at a time. As feature sizes continue to decrease in applications such as integrated circuits and memory devices, ALD is becoming the preferred (and in some cases only) option for depositing some film components. Weaknesses associated with conventional temporal ALD include its speed (it is a relatively slow batch process) and its need for a vacuum chamber, which hinders its scalability.

Conventional temporal ALD operates by sequentially inserting two or more chemical precursor gases into a vacuum chamber, with evacuation and purge steps in between the exposures. If suitable experimental conditions are used, a single atomic layer of the material is formed after each sequence, and the sequence is repeated multiple times to build up a film. Hence conventional temporal ALD separates the two precursor gases in time. In contrast, spatial atomic layer deposition (SALD) techniques have been developed, which separate the two precursors in space, rather than in time. The substrate is moved between the two precursor gases to replicate the sequential exposures. This eliminates or reduces the evacuation and purge steps that make temporal ALD slow.

Atmospheric Pressure SALD (AP-SALD) can produce thin film layers of materials (e.g. metal oxides) that are compact, conformal, and pinhole-free and can deposit thin films at approximately room temperature. This is one to two orders of magnitude faster than conventional ALD, and is scalable. Notably, AP-SALD is also compatible with roll-to-roll manufacturing and demonstrated to work on glasses, glasses coated with transparent conducting oxides, semiconducting wafers, foils, fabrics and plastic surfaces. These advantages make AP-SALD very attractive for high-throughput manufacturing of large-area, low-cost electronics, such as photovoltaics, batteries, and microelectronics, as well as functional coatings, such a barrier films and antimicrobial coatings.

Therefore, there is provided a novel apparatus and method of thin film deposition.

### SUMMARY

The present disclosure includes a novel thin, film or thin layer deposition method generally including at least one reactor head that is modular and configurable for functional flexibility and scalability to produce thin films. Thin layer deposition may include spatial atomic layer deposition and/or chemical vapor deposition. The reactor head may include different types of components such as, but not limited to, precursor gas slits, a plasma source, exhaust slits, a heating channel and/or a cooling channel for different types of depositions. The interspaced elevation and widths of each component may be adjusted to facilitate and control the flow of gases. A positioning system with a mounting element for the reactor head is configured to adjustably maintain the orientation and position of the reactor head relative to the substrate(s). The positioning system may be configured with at least one displacement measuring device and at least one actuator. A heating stage with suction may be used to heat a substrate and to hold substrates of different size, geometry, and thickness. The heating stage may be configured with zone-controlled heating to provide different temperatures at different locations. A linear motor positioning system may be used to oscillate the substrate relative to the modular reactor head. The system may deposit thin films by spatial atomic layer deposition or chemical vapor deposition and produce films with uniform thickness and/or composition or varying thickness and/or composition.

In one aspect of the disclosure, there is provided a modular reactor head for use with a thin film deposition system including a set of modular components, the set of module components adjacent each other in a first direction within the reactor head; wherein the set of modular components may be positioned relative to each other in a second direction, the second direction substantially perpendicular to the first direction; wherein the set of modular components include at least one precursor gas modular component for depositing at least two precursor gases onto a substrate.

In another aspect, the set of modular components includes at least two precursor gas modular components. In a further aspect, the at least two precursor includes a reactor channel; and a reactor channel opening. In a further aspect, the reactor channel opening delivers a gaseous or liquid material with a higher exit velocity at one end of the reactor channel opening than at an opposite end of the reactor channel opening. In an aspect, the set of modular components includes at least one of a precursor fluid component, an exhaust modular component, an inert gas modular component, a temperature control modular component, chemical modular component, a cleaning modular component and a plasma source modular component. In a further aspect, the temperature control modular component includes a metal plate for controlling a temperature of a modular component adjacent the temperature control modular component. In yet a further aspect, the temperature control modular component includes a reactor channel for either receiving a cooling liquid to cool the metal plate or a heating liquid to heat the metal plate. In yet another aspect, the set of modular components are mounted at predetermined heights with respect to each other. In another aspect, the precursor fluid modular component includes actuators to control precursor fluid deposition.

In another aspect of the disclosure, there is provided a thin film deposition system including a substrate stage for supporting a substrate; a modular reactor head for depositing thin films onto the substrate, the modular reactor head including a set of modular components, the set of module components adjacent each other in a first direction within the reactor head; wherein the set of modular components may be positioned relative to each other in a second direction, the second direction substantially perpendicular to the first direction; wherein the set of modular components include at least one precursor gas modular component for depositing at least two precursor gases onto a substrate; and a modular reactor head positioning system for positioning the modular reactor head with respect to the substrate on the substrate stage.

In a further aspect, the modular reactor head positioning system includes a linear displacement system. In yet another aspect, the linear displacement system includes a set of displacement measuring devices; and a set of linear actuators. In yet a further aspect, the modular reactor head positioning system including a leveling system for gap control between the modular reactor head and the substrate stage. In an aspect, the substrate stage includes a vacuum system for holding the substrate against the substrate stage. In another aspect, the substrate stage includes an upper plate for supporting the substrate; and a heating component for heating the upper plate. In yet a further aspect, the substrate stage includes a linear motor system.

### BRIEF DESCRIPTION OF THE DRAWINGS

For a clear understanding of the disclosure, some embodiments of the present disclosure are illustrated as an example and are not limited to the figures of the accompanying drawings, in which:

FIG. 1 illustrates an embodiment of a thin layer deposition system;

FIG. 2 is an isometric view of an embodiment of a modular reactor head including a plurality of modular components;

FIG. 3A is a bottom view of the modular reactor head of FIG. 2;

FIG. 3B is a bottom perspective view of the modular reactor head of FIG. 2;

FIG. 3C is a bottom view of a modular component having a plurality of slits;

FIG. 4 is a side view of the modular reactor head of FIG. 2;

FIG. 5A is a side view of an embodiment of a modular reactor head having a plurality of modular components with adjustable interspaced elevations;

FIG. 5B is a front view of the modular reactor head of FIG. 5A;

FIG. 5C is an isometric view of the modular reactor head of FIG. 5A;

FIG. 6 is a perspective view of an embodiment of a cooling modular component;

FIG. 7 is a perspective view of an embodiment of a modular reactor head;

FIG. 8A is a front view of an embodiment of a thin film deposition system including a reactor head positioning system;

FIG. 8B is a perspective view of the thin film deposition system of FIG. 8A;

FIG. 9A is a perspective view of an embodiment of a substrate stage;

FIG. 9B is a cross-sectional view of the substrate stage of FIG. 9A;

FIG. 10 is a perspective view of four (4) substrates held on the substrate stage of FIG. 9A;

FIG. 11 is a bottom perspective view of an embodiment of an upper plate;

FIGS. 12A to 12B illustrate different configurations of the heating stage;

FIG. 13A is a schematic view of a reactor head having three reactor channels configured to deliver a uniform flow profile;

FIG. 13B is a schematic view of a reactor head having one reactor channel configured to deliver a non-uniform flow profile;

FIG. 14A is a schematic diagram of a geometry for a reactor channel having a non-uniform flow profile for an embodiment of a modular component;

FIG. 14B is a graph showing Computational Fluid Dynamics simulated results showing the flow velocity along the outlet of the precursor gas slit for the reactor channel geometry of FIG. 14A;

FIG. 14C is a schematic view of a design for an embodiment of a reactor head having a non-uniform flow profile;

FIG. 14D is a photograph of a 3D print of the reactor head of FIG. 14C;

FIG. 15 are photographs of films of zinc oxide (ZnO) produced using the reactor head of FIG. 14C;

FIG. 16A is a graph showing measurements of ZnO film thickness across the substrate for a thickness gradient film from FIG. 15;

FIG. 16B shows a map of film thickness over the surface of the substrate from FIG. 16A;

FIG. 17A is a perspective view of an embodiment of a modular component that includes two symmetrical half-pieces;

FIG. 17B is an exploded perspective view of the modular component of FIG. 17A;

FIG. 18 is a perspective view of an embodiment of a substrate stage mounted on a linear motor system;

FIG. 19 shows a flow diagram for a method for depositing a thin film with a modular reactor head; and

FIG. 20 shows a flow diagram for a roll-to-roll method for depositing a thin film with a modular reactor head.

### DETAILED DESCRIPTION

The terminology used herein is for the purpose of describing specific embodiments only and is not intended to be limiting of the system or disclosure. As used herein, the term “and/or” includes any and all combinations of one or more of the associated listed items. As used herein, the singular forms “a,” “an,” and “the” are intended to include the plural forms as well as the singular forms, unless the context clearly indicates otherwise. It will be further understood that the terms “comprise(s)” and/or “comprising,” when used in this specification, specify the presence of stated features, steps, operations, elements, and/or components, but do not preclude the presence or addition of one or more other features, steps, operations, elements, components, and/or groups thereof.

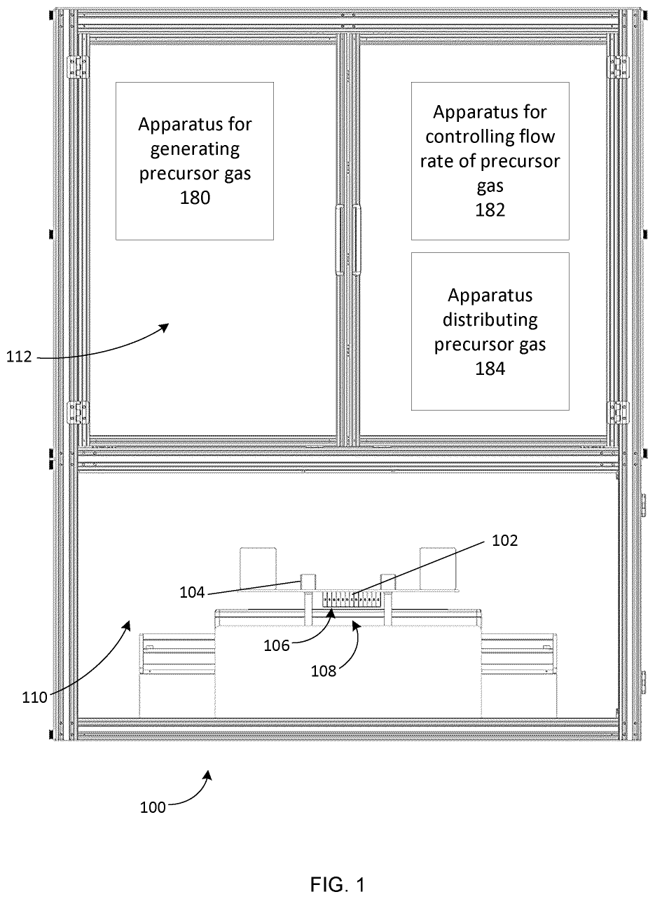

FIG. 1 shows an embodiment of a thin film, or thin layer deposition system 100, including a modular reactor head 102, a reactor head positioning system 104 and a substrate stage 108 for supporting a substrate 106. In one embodiment, the reactor head positioning system 104 controls the orientation of the reactor head 102 relative to the substrate 106, such as in a linear direction, rotation along an axis and/or a distance between the reactor head and the substrate 106. The substrate stage 108 controls the position of the substrate 106 relative to the modular reactor head 102. In operation, the modular reactor head 102 deposits thin films of precursor gas or materials onto the substrate as will be discussed in more detail below.

The phrase “thin layer” or “thin film” as used herein refers to a layer of material deposited by spatial atomic layer deposition (SALD) and/or spatial chemical vapor deposition (SCVD). It has been shown that by controlling the processing conditions so that the precursor gases can mix in the gas phase (are not isolated from each other), chemical vapor deposition can occur instead of atomic layer deposition. This results in a higher thin film deposition rate, which is advantageous for some applications, while still producing conformal, pinhole-free films, with accurate control over the film thickness at the nanometer scale. As such, the phrase “thin layer deposition” refers to spatial atomic layer deposition and/or spatial chemical vapor deposition.

In the current embodiment, the modular reactor head 102, reactor head positioning system 104, and substrate stage 108 are positioned in a lower cabinet 110. Equipment to deliver precursor gases to the modular reactor head is placed in the upper cabinet 112. This equipment will be well understood by one skilled in the art. In one embodiment, the equipment may include equipment for generating gases 180 of precursor chemical such as, but not limited to, bubblers and bubbler heaters, equipment to control a flow rate 182 of the gases such as, but not limited to mass flow controllers and equipment 184 to distribute the gases, such as, but not limited to valves, tubing and manifolds. In one embodiment, the precursor gases may be directly inputted into the upper cabinet from an external source or may be generated from liquid or solid chemicals by bubbling or nebulizing a liquid chemical material or heating a solid chemical material. In another embodiment, instead of or along with, a precursor gas, a liquid may be transmitted from the upper cabinet to the modular reactor head.

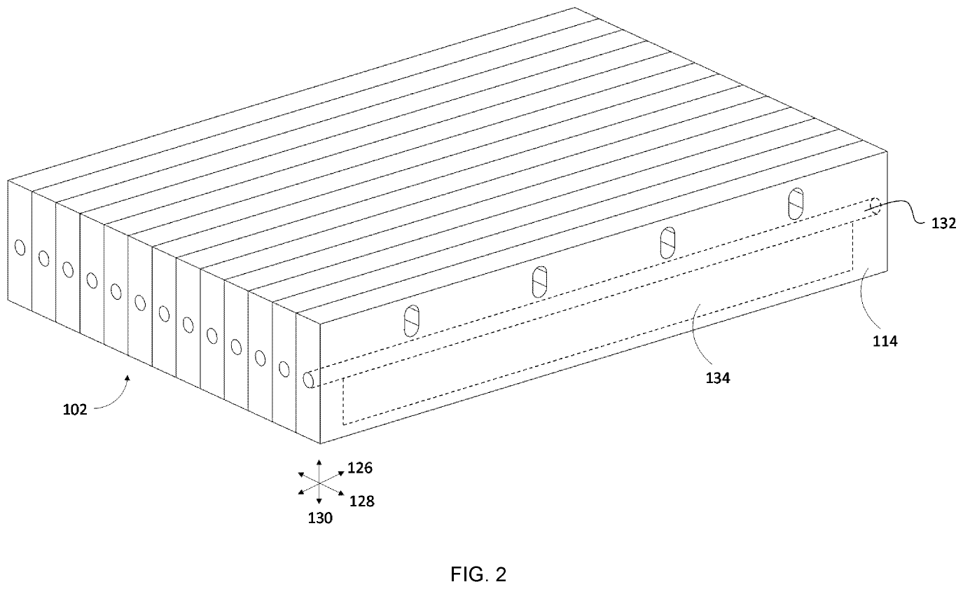

FIG. 2 is an isometric view of an embodiment of a modular reactor head 102. The module reactor head 102 includes a plurality, or set, of modular components 114. In one embodiment, the module reactor head 102 may include a set of modular components 114 whereby each of the modular components perform a single functionality to enable thin layer deposition. In some embodiments, multiple module components may perform a same functionality as other module components while in other embodiments.

In one embodiment, the reactor head 102 may be oriented parallel to the substrate stage 108 with the set of modular components 114 adjacent each other in a plane oriented along a first direction 128. A length of each of the set of modular components 114 may be seen as extending in a second direction 126 substantially perpendicular to the first direction 128. The reactor head 102 may be positioned at a distance from the substrate 106, where the distance may be measured along a direction 130 substantially orthogonal to the first and second directions. In some embodiments, the distance may be measured at an angle from the reactor head. Each of the set of modular components 114 may perform different functionalities as discussed in more detailed below.

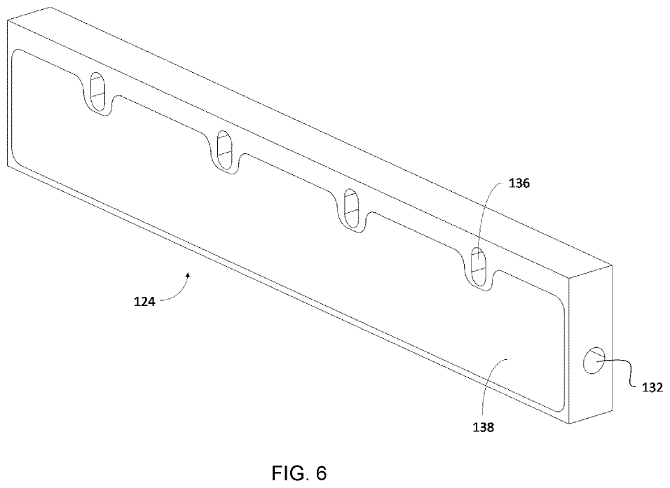

In one embodiment, as shown in dotted lines in FIG. 2, a modular component 114 includes a reactor channel 132 for receiving a gas or a liquid and a reactor channel opening 134 (which may be seen as a slit) which allows the gas or liquid to enter or leave the reactor channel 132. Reactor channel openings typically have a length oriented parallel to the second direction 126, however in alternative embodiments the reactor channel opening may be oriented at an angle relative to the second direction 126. In some embodiments, the modular component 114 may not include a reactor channel opening (such as disclosed with respect to FIG. 6) or may not include a reactor channel or a reactor channel opening where the modular component may be a heating or cooling element powered by a power source. Non-exclusive examples of modular components include, but are not limited to, precursor gas components, exhaust components, inert gas components, heating components, cooling components, plasma sources, and other components according to various embodiments of the present disclosure.

If a modular component 114 is supplied with a precursor gas that passes through the modular component 114 from the precursor gas source to the substrate, the modular component 114 may be seen as a precursor gas component and the reactor channel opening referred to as a precursor gas opening. As thin layer deposition typically requires at least two different precursor gases, at least two of the modular components of a reactor head will provide the functionality of a precursor gas modular component. Alternatively, if a modular component 114 is supplied with an inert gas, the modular component may be seen as an inert gas modular component and the reactor channel opening referred to as an inert gas opening. If a modular component 114 is supplied with a precursor fluid, e.g. liquid and actuator, the modular component may be seen as a precursor fluid modular component and be used to introduce a different way of nanomanufacturing techniques, such as but not limited to, selective-area deposition, slot-die coating, inkjet printing or spray deposition. If a modular component 114 is coupled to a vacuum source to draw gas into its reactor channel 132 through the reactor channel opening, the modular component 114 may be seen as an exhaust modular component and the reactor channel opening referred to as an exhaust opening. A modular component 114 may be seen as a thermal control modular component whereby thermal fluid may pass through the reactor channel. In a thermal control modular component, the reactor channel 132 does not include a reactor channel opening. If the thermal control modular component provides heat, the modular component may be referred to as a modular heating component. If the thermal control modular component provides cooling, the thermal component may be referred to as a modular cooling component. If plasma is introduced into the reactor channel, the modular component may be seen as a plasma source or plasma modular component. Alternatively, if the modular component 114 is supplied with a chemical, such as, but not limited to, a cleaning agent or supplied with compressed air, the modular component may be seen as a cleaning modular component and may be used to clear the reactor channel for maintenance purposes or for possibly cleaning the substrate, if necessary. In alternative embodiments, the chemical may be a reducing agent whereby a material (such as a metal) on the substrate may catalyze other materials (such as metal ion salts) due to the reducing agent. In another embodiment, the chemical may used to perform a surface modification treatment or etching on the substrate.

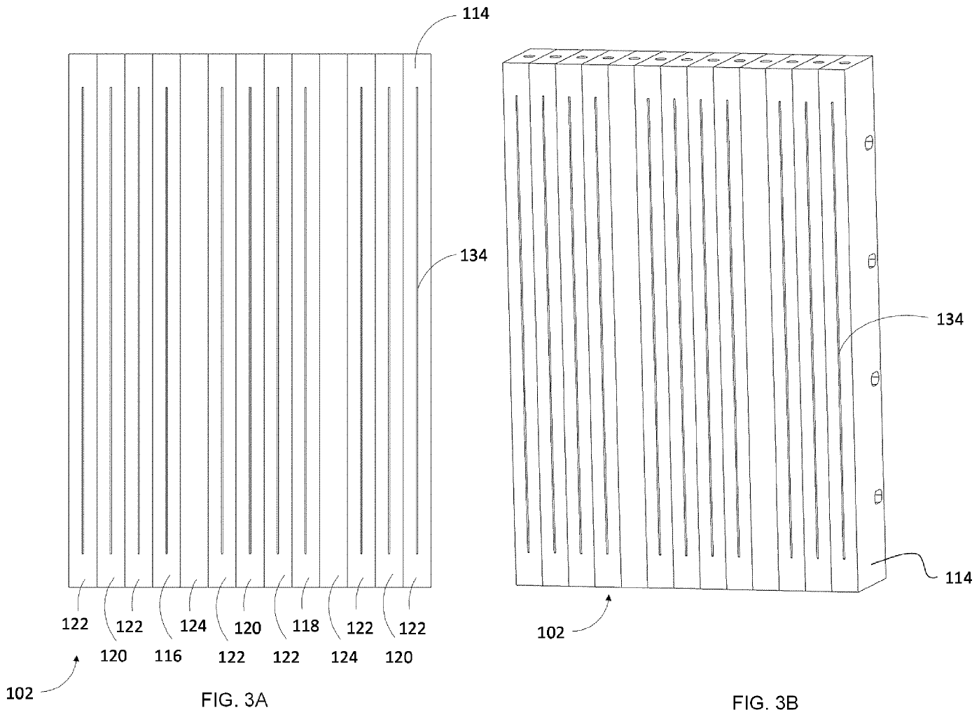

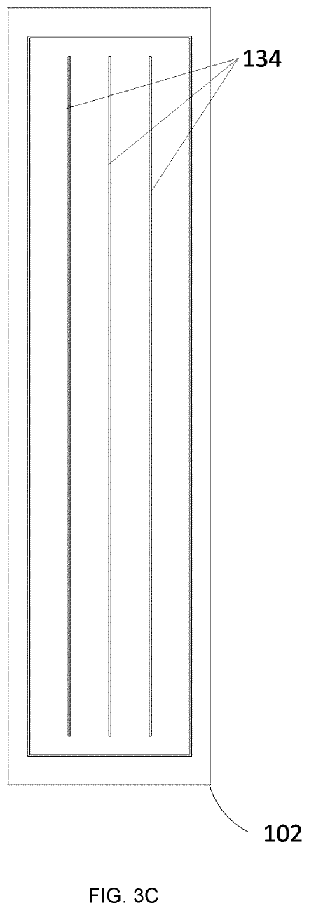

FIGS. 3A and 3B are bottom views of the modular reactor head 102 with the reactor channel openings 134. In the current embodiment, the set of modular components 114 includes a first precursor gas component 116, a second precursor gas component 118, three inert gas components 120, six exhaust components 122, and two cooling components 124, however, it will be understood that this is simply one arrangement of the how the modular components may be set up. In some embodiments, the set of modular components includes at least two precursor gas components, however, in other embodiments, one modular component may be used to deliver more than one precursor gas such that the set of modular components include only one modular component for delivering precursor gases.

In the present embodiment, the set of head modular components 114 is arranged to effectively separate the precursor gases for atomic layer deposition (ALD), by positioning at least one of the inert gas components 120 and at least one of the exhaust components 122 between the first precursor gas component 116 and the second precursor gas component 118. The arrangement of modular components 114 is flexible so that in alternative embodiments the arrangement of modular components 114 may be configured to mix the precursor gases (e.g. the first and second precursor gas components 116 and 118 could be placed directly adjacent to each other, without exhaust components 122 or inert gas components 120 in between) for chemical vapor deposition (CVD).

Each modular reactor component 114 may be positioned with a long axis of the modular reactor component 114 parallel with the second direction 126. The set of modular components 114 may be arranged to position each modular component 114 adjacent to at least one other modular component 114 where the plurality of modular components 114 extends in the first direction 128. In other words, the individual modular components 114 of the modular reactor head 102 are stacked horizontally for easy assembly. The sequence of the modular components 114 depends on the configuration of the reactor head 102, where the sequence may be altered by altering the position of one or more of the modular components 114 (i.e. changing the sequence).

The modular reactor head of the disclosure may allow a thin film deposition system to be scaled easily by increasing the number of individual modular components or by increasing the length of the reactor channel openings. By increasing the number of precursor gas modular components, or by increasing the number of reactor channel openings in a modular component, the number of ALD cycles that occur each time the substrate(s) passes underneath the modular reactor head is increased. FIG. 3C is a bottom view of a modular component having three slits, or reactor channel openings 134, although in alternative embodiments a modular component may have two, four, or more slits 134. Each slit 134 may have a respective reactor channel 132 or the slits 134 may be connected with a single reactor channel. Longer slits may enable multiple substrates or larger substrates to be coated with thin films.

The modular reactor head 102 may allow functional flexibility, where different types of individual modular components can be easily added, such as cooling channels, heating channels, plasma sources, and precursor gas modular components having reactor channel openings with unique features (for example non-uniform gas delivery to produce film gradients, as will be discussed below). Each modular component may be customized, installed or swapped out, for different functions and purposes.

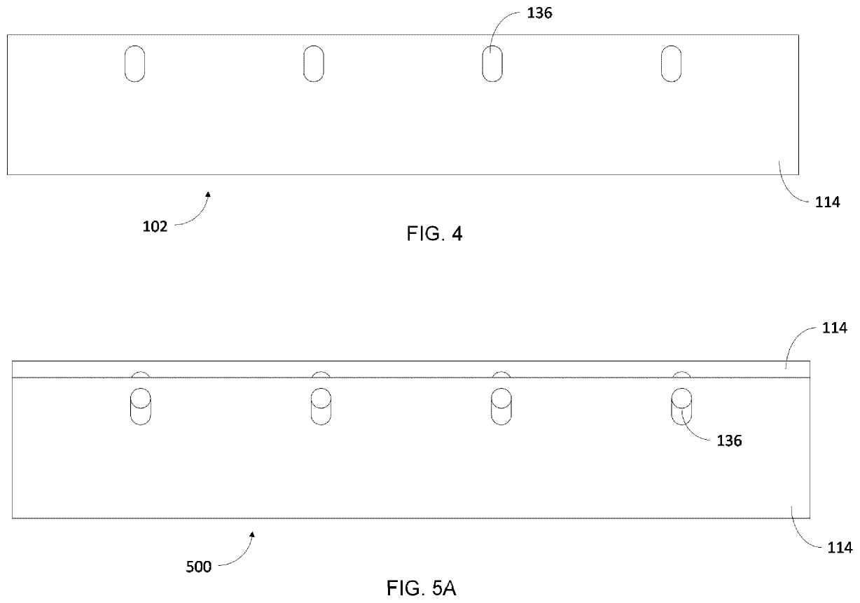

FIG. 4 is a side view of the modular reactor head 102. Each modular component 114 includes a plurality of slots 136. Each slot 136 is configured to accommodate a mounting rod (not shown) to support the modular component 114 within the modular reactor head 102. In the current embodiment, each slot 136 is larger than a respective mounting rod in the direction parallel to the plane 130 to allow the position of each modular component 114 to be varied with respect to the position of the mounting rod, and thereby allow the position of each modular component 114 to be varied along the plane 130. In other words, each modular component 114 may be slidably mounted in the modular reactor head 102 to allow adjustment of the position of each modular component 102 along the plane 130.

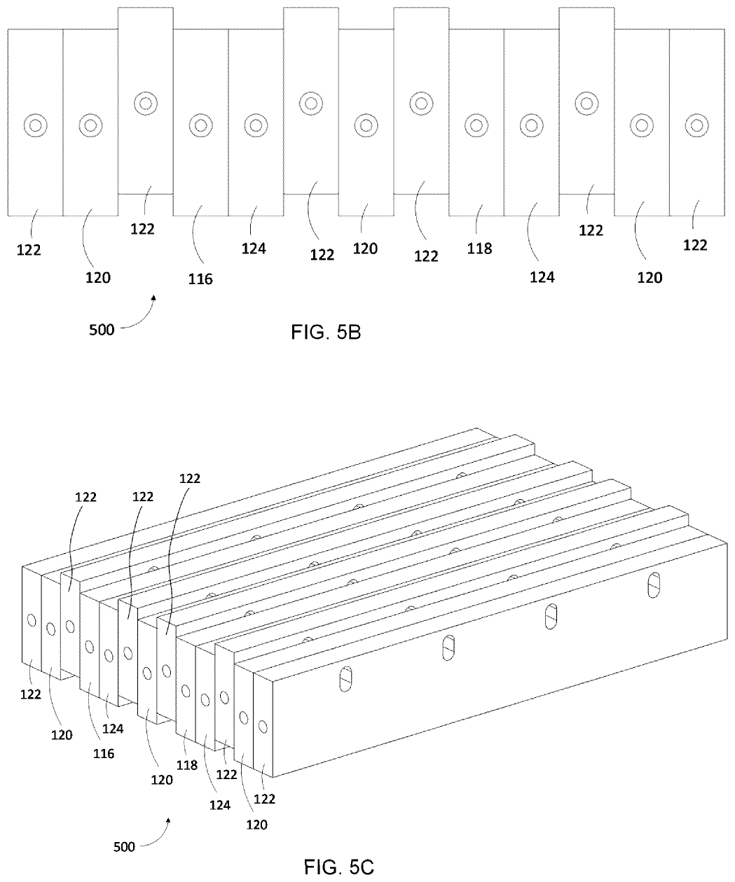

FIGS. 5A, 5B, and 5C show a side view, a front view, and an isometric view of an embodiment of a modular reactor head 500 having a plurality of modular components 114 with adjustable interspaced elevations and at varying heights. The modular reactor head 500 may be substantively similar to modular reactor head 102, and may be formed using the same plurality of modular components 114 used to form modular reactor head 102. In one embodiment, the reactor head 500 may include first precursor gas component 116, second precursor gas component 118, inert gas components 120, exhaust components 122, and cooling components 124, however, it will be understood that the modular components may be varied with at least two of the module components being precursor gas components. The height of an individual modular component 114 (and thereby the height of a respective reactor channel opening) with respect to the substrate and other modular components can be mechanically adjusted precisely relative to the adjacent modular component(s) 114 to achieve a desired interspaced elevation. For example, the height of each modular component 114 may be adjusted by sliding that modular component 114 (perpendicular to the rod axis) relative to an adjacent modular component 114. The interspaced elevation adjustment may provide more flexibility and control over gas flows. In FIGS. 5A, 5B, and 5C, the exhaust components 120 are moved up slightly along the plane 130 to create a region that the precursor gases will naturally flow into to improve the exhaust efficiency and prevent or reduce the likelihood of gas mixing.

FIG. 6 is a perspective view of an embodiment of a modular component that may be used as a modular cooling (or heating) component 124. In some embodiments of a modular reactor head, thermal components (including heating and cooling components) may be positioned adjacent a precursor gas component. Thermal components allow the temperature of at least a portion of the modular reactor head to be controlled. For example, the temperature of a precursor gas component adjacent a thermal component may be controlled, relative to the temperature of the heated substrate stage, to obtain desired thin film deposition conditions. In one embodiment, the reactor channel 132 of the modular cooling component 124 includes a cooling plate 138 to remove heat from an adjacent precursor gas modular component. In one embodiment, the cooling plate is made of a metal, such as, but not limited to, copper. In one embodiment, chilled water may be circulated inside the reactor channel 132 of the modular cooling component to provide a temperature difference between the modular cooling component and the adjacent precursor gas modular component. In alternative embodiments, the chilled water can be replaced with hot water or a heating element to heat up the precursor gas openings of the precursor gas modular components. More specifically, with a modular cooling component, the cooling, plate is cooled as a chilled liquid is passed through its reactor channel to draw heat from the adjacent modular component such as to ensure chemical reactions occur on the substrate rather than in the adjacent modular component. Alternatively, for a modular heating element, the modular component cooling plate or a heating element is heated up to heat up the reactor channel of an adjacent modular component (such as an adjacent precursor gas modular component) for precursor gases that are prone to unwanted condensation on cold surfaces.

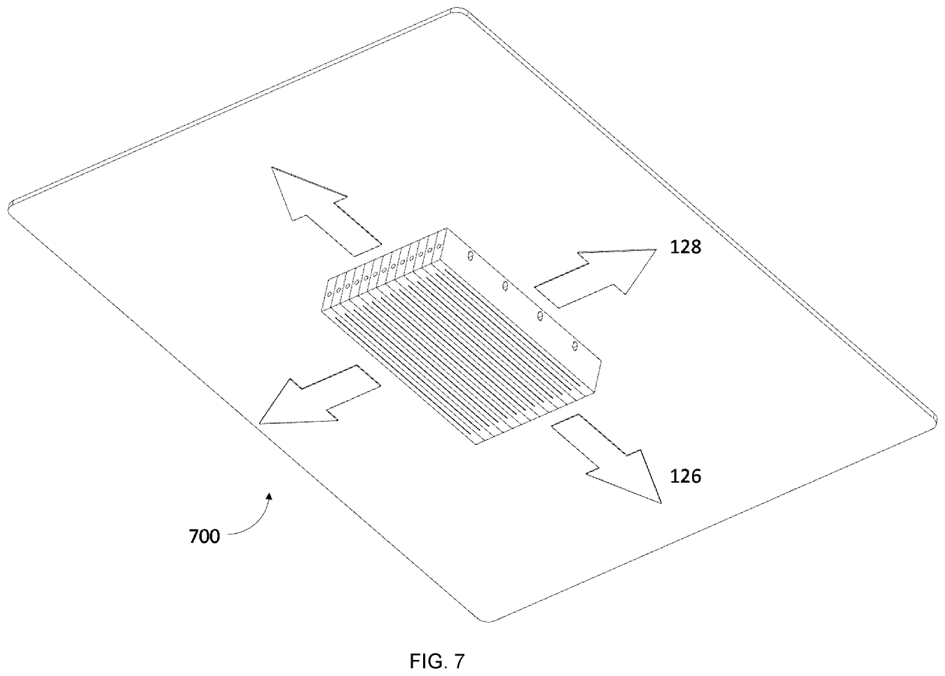

FIG. 7 is a perspective view of an embodiment of a modular reactor head 700. The modular reactor head 700 may be substantively similar to modular reactor head 102 and modular reactor head 500. The modular reactor head 700 can be scaled within the thin film deposition system to increase the thin film deposition area and/or throughput. For example, the scale of the modular reactor head 700 can be increased in direction 126 by using modular components with reactor channel openings having an increased length in direction 126. Increasing the scale of the modular reactor head 700 in direction 126 may increase the size of the film deposited on a substrate in direction 126 and thereby increase the area of the film or the number of substrates deposited. The scale of the modular reactor head 700 can be increased in the direction 128 by increasing the number of modular components forming the reactor head 700, for example by adding additional modular components, such as, but not limited to, precursor gas components. Increasing the scale of the modular reactor head 700 in direction 128 may increase the thickness of a film deposited in one pass of the modular reactor head 700, and thereby increase the throughput of the modular reactor head 700.

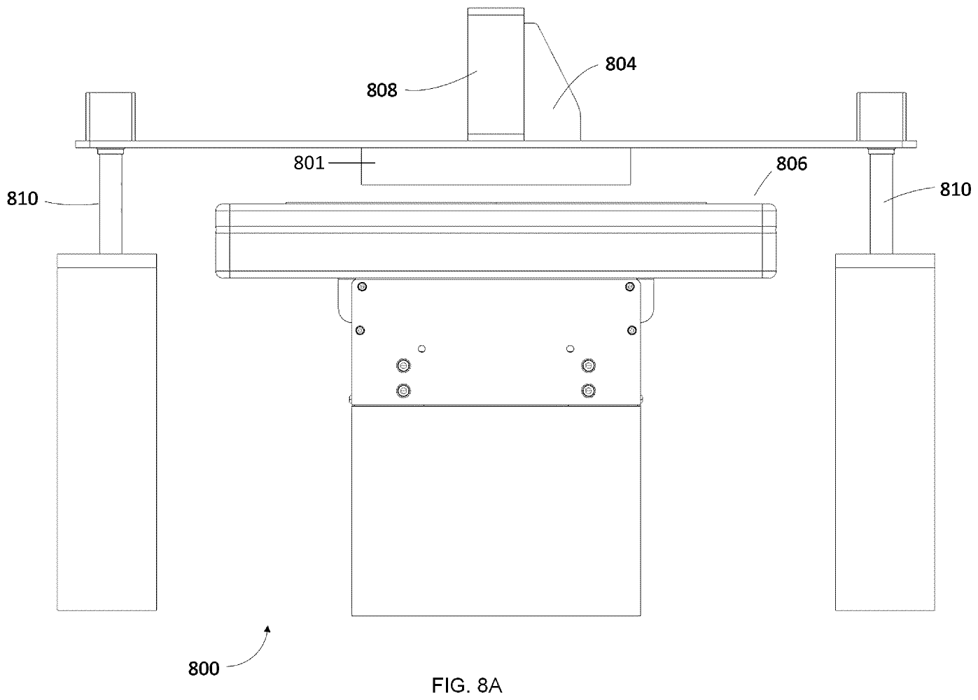

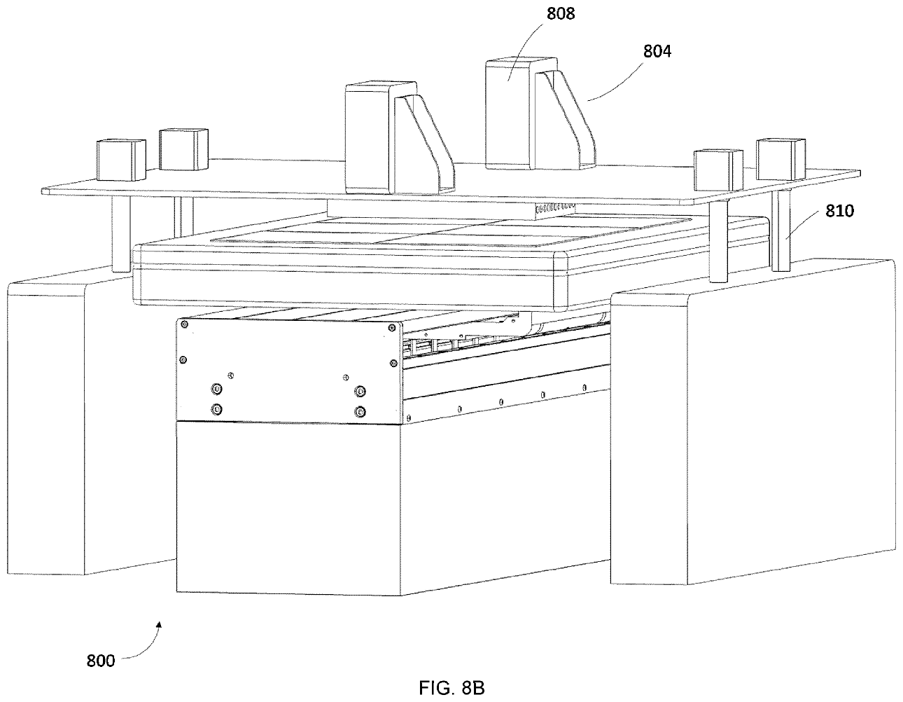

FIGS. 8A and 8B show a front view and a perspective view of an embodiment of a thin film deposition system. The thin film deposition system 800 includes a reactor head positioning system 804. The thin film deposition system 800 may be substantively similar to the thin film deposition system 100. The reactor head positioning system 804 includes a mounting element (not shown) for receiving the reactor head 801, such as modular reactor head 102, and is configured to adjustably maintain the orientation and position of the reactor head 801 relative to a substrate 806 upon which the thin film is deposited. In particular, the reactor head positioning system 804 is configured to control a distance between the modular reactor head 800 and the substrate 806. In the present embodiment, the reactor head positioning system 804 includes a linear displacement system including one or more laser displacement sensors 808 which function as displacement measuring devices and one or more linear actuators 810 which function as displacement controlling devices. In alternative embodiments, other displacement measuring devices and actuators may be used. In conjunction with the displacement measuring devices and actuators, software, such as in the form or modules or instructions stored on a computer readable medium, is used to dynamically monitor and adjust the spacing between the reactor head 801 and the substrate(s) 806. In one embodiment, a resolution of 1 micrometer is used. The ability to accurately control the reactor-substrate spacing (i.e. in plane 130) can provide control over whether the precursor gases remain isolated (ALD occurs) or mix in the gas phase (CVD occurs). An example of a conventional positioning system is a floating wafer system, however floating wafer systems are limited to substrates that can be floated. In other words, the positioning system of the present embodiment may provide greater flexibility in the size, number or type of substrates that may be used for thin film deposition. In the present embodiment the reactor head positioning system 804 is configured to move the reactor head 801 along the plane 130 to control the reactor-substrate spacing between the substrate 806 and the reactor head 801, however in alternative embodiments the substrate 806 may move along the plane 130 while the reactor head 801 remains stationary.

The deposition system may be equipped with loading and unloading mechanisms for the substrates, such as robotic arms, to fully automate the manufacturing process. The deposition system may also be compatible with roll to roll technologies, such as film deposition on plastics, fabrics or foils. For roll-to-roll systems, the substrate stage may be configured to be compatible with a continuous web of plastic, fabric or foil, for example the substrate stage may include rollers to hold a portion of the web proximate the reactor head at an at least approximately constant distance from the reactor head, and the system may control the position of the web and number of depositions to achieve a desired thickness on the web by rolling/unrolling the web.

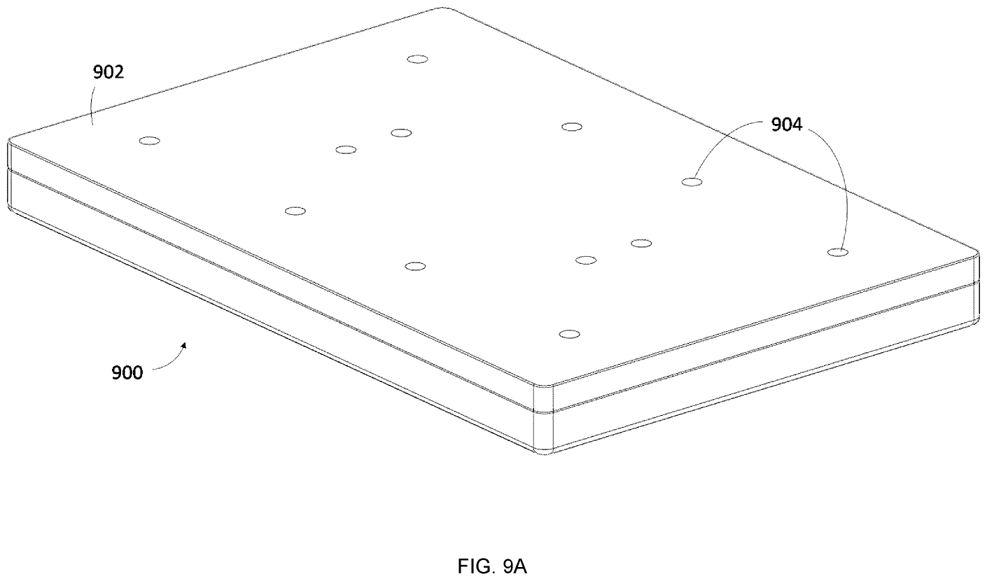

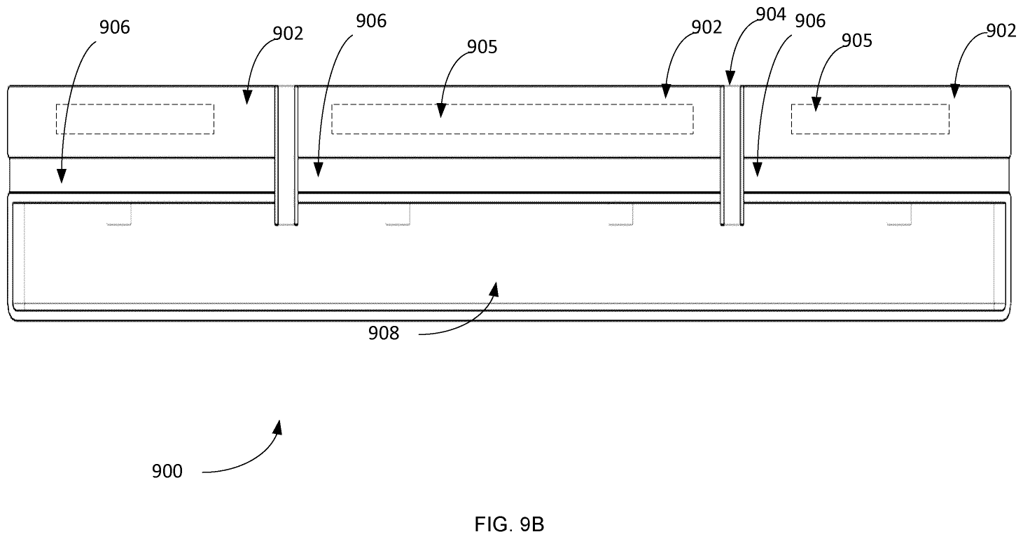

FIG. 9A is a perspective view of an embodiment of a substrate stage 900. The substrate stage 900 may be substantively similar to substrate stage 108. FIG. 9B shows a cross-sectional view an embodiment of the substrate stage 900. In the present embodiment, the substrate stage 900 includes an upper plate 902 having a plurality of holes 904, a heating component 905 (shown in dotted lines), such as a heating element that is embedded within the upper plate 902 and a vacuum reservoir 908 fluidly coupled to the plurality of holes 904 to provide suction to the plurality of holes 904. The upper plate 902 may be an upper metal plate.

The upper plate 902 is separated from the vacuum reservoir 908 by a thermal-insulation layer 906, which may be an air gap, to thermally insulate the vacuum reservoir 908 from the upper plate 902 that is heated by a heating element 905. A substrate (not shown) may be placed on the upper plate 902, and when suction is provided, the plurality of holes 904 in the upper plate 902 may firmly hold the substrate in place atop the upper plate 902. In other words, the vacuum reservoir 908 coupled to the plurality of holes 904 in the upper plate 902 form a mechanism to hold a substrate to the substrate stage 900.

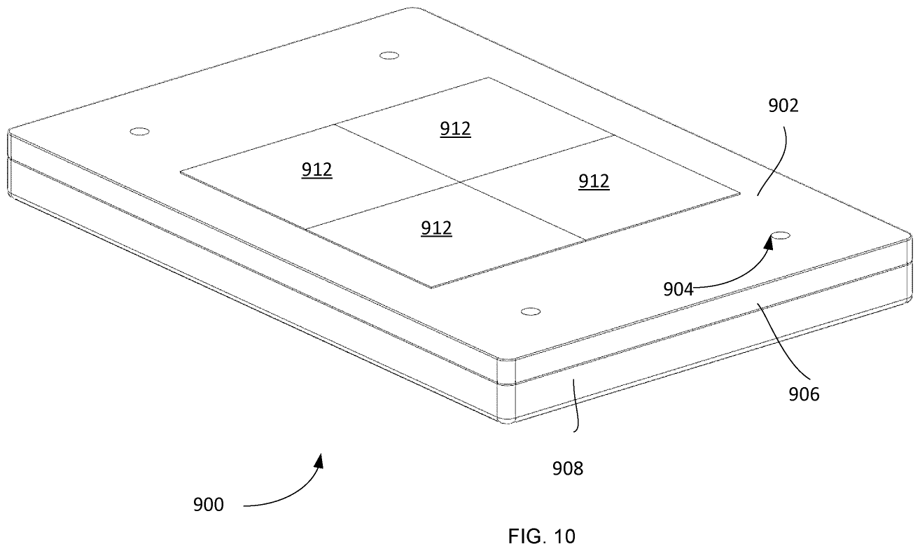

FIG. 10 is a perspective view of four (4) substrates 912 held on the substrate stage 900. Substrates of varying size, geometry, thickness, and materials (e.g. glass, silicon wafer) can be heated on or by the upper plate 902 (heated by the heating element) and held by the vacuum holding mechanism 908 provided the substrate is approximately within the substrate stage dimensions and is flat. The plurality of holes 904 can be configured to accommodate substrates 912 of different sizes and geometry. Caps (not shown) may be added to the plurality of holes 904 to prevent or reduce the likelihood of suction at specific locations on the substrate stage 900 as needed.

In one embodiment, the upper plate 902 is offset from the vacuum reservoir 908 (which provides the suction to hold the substrates 912 down) by a predetermined distance, such as approximately 10 mm or more, to provide the air gap 9 for insulation. As discussed above, insulation material can be added to isolate the vacuum reservoir 908 and underlying system components from the heat generated by the heating element 905.

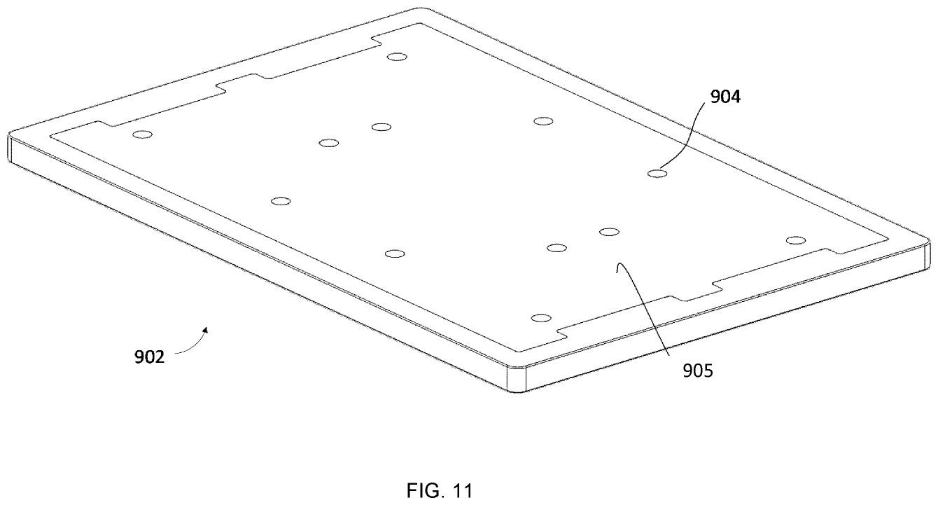

FIG. 11 is a bottom perspective view of an embodiment of an upper plate 902. in the current embodiment, the upper plate 902 includes a heating component, such as heating 905 embedded inside. In alternative embodiments more than one heating element 905 may be embedded within the upper plate 902 such as discussed below. Thermal grease may be used to increase the thermal conductivity between the heating element 905 and the upper plate 902. The heating provided by the heating component may alternatively be implemented via infra-red heating elements or laser heating elements whereby these heating elements may perform other functionality along with heating,

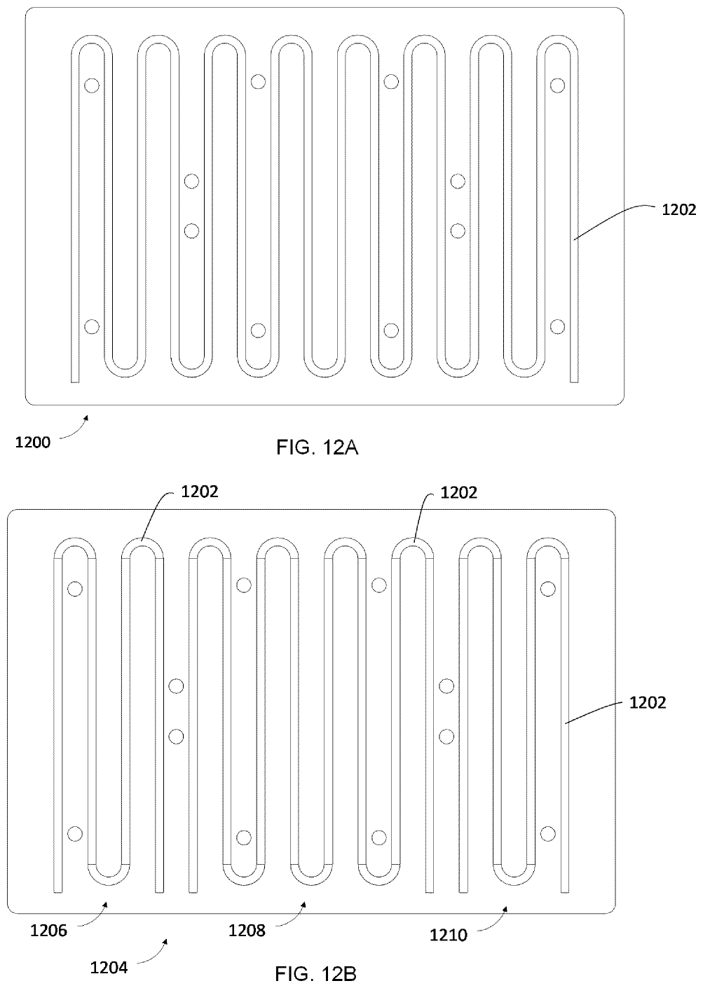

FIG. 12A shows a top view of an embodiment of heating element 1200 having a single heating unit 1202. FIG. 12B shows a top view of an embodiment of heating element 1204 having three heating units 1202 positioned in three heating zones 1206, 1208, and 1210 whereby heating element 1204 may be seen as being configured for zone-controlled heating. In alternative embodiments, the heating element 1204 may have two, four, or more heating units and therefore two, four, or more corresponding heating zones that may be individually controlled. A heating element may be configured for uniform or non-uniform heating, depending on the selection and placement of heating elements. This modular heating element design helps to improve energy use for different substrate geometries, enables uniform heating and non-uniform zone heating of substrates, and enables rapid prototyping by allowing depositions to be performed with multiple substrates at different temperatures. Furthermore, non-uniform/zone heating can be used to determine the operating temperature ranges for ALD mode and CVD mode for different chemicals. In alternative embodiments, gradient heating may be used. Heating element 1200 and heating element 1204 may be substantively similar to heating element 905.

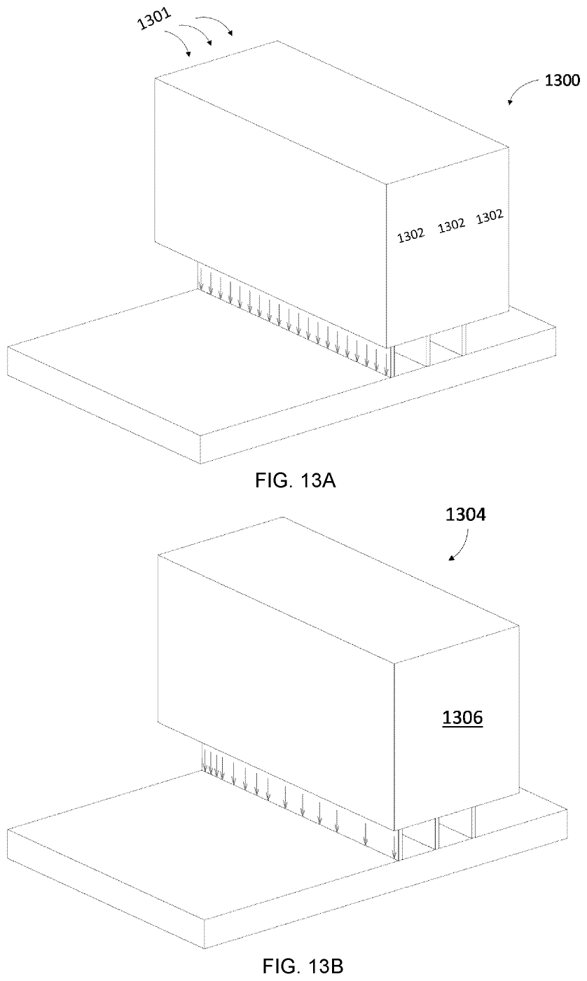

FIG. 13A is a schematic view of a reactor head 1300 having modular components 1301 with reactor channels 1302 configured to deliver a uniform flow profile such as shown by the arrows under the reactor channels. Conventional ALD techniques typically deposit films with uniform thickness and composition, which may be achieved by delivering precursor gases with a uniform flow profile. The thin layer deposition systems of the present disclosure are capable of depositing uniform films as well as films with non-uniform thickness and composition. The geometry of the reactor channels in the precursor gas modular components in a modular reactor head may be modified to control the flow profile(s) of the gas(es) through the precursor gas, or reactor channel, openings, such that different amounts of precursor gas can be delivered to different locations on the substrate.

FIG. 13B is a schematic view of a reactor head 1304 having modular components wherein at least one of the modular components has a reactor channel 1306 configured to deliver a non-uniform flow profile such as shown by the arrows under the reactor channel 1306 wherein the fluid flows faster at one end where the arrows are closer together than the other end where the arrows are more spaced apart. The non-uniform flow profile enables more material to be deposited at locations where more precursor gas is delivered. Depending on the flow profile(s) of the fluid, gas(es) or liquids, linear, non-linear, or complex thickness or composition variations may be produced across the film. In one embodiment, a specific flow profile for a precursor gas modular component can be obtained by using Computational Fluid Dynamics (CFD) simulations to design a geometry of the reactor channel, or precursor gas, slit or opening. FIGS. 13A and 13B illustrate how the precursor gas reactor channel openings can be customized to produce uniform flows of precursor gases and hence films with uniform thickness and composition (FIG. 13A) or non-uniform flows of precursor gases and hence films with thickness and/or composition gradients (FIG. 13B).

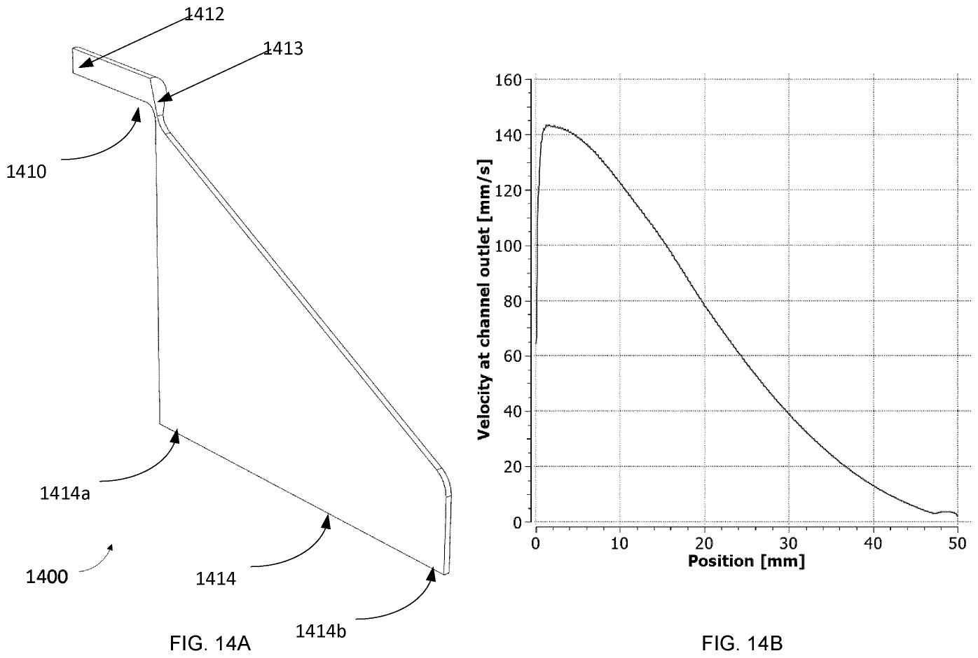

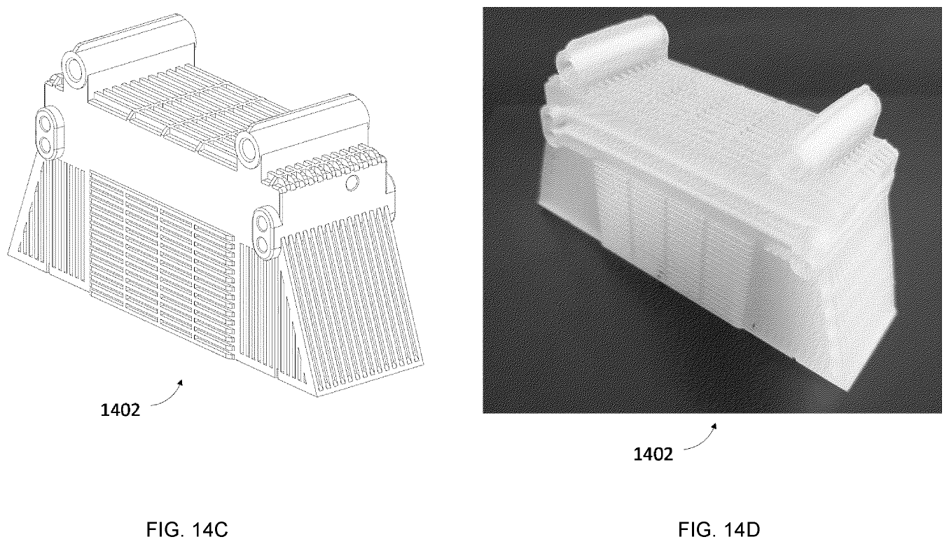

FIG. 14A shows a schematic geometry or a portion of a reactor channel 1400 to deliver a non-uniform flow profile when used in a modular component, for example a modular component 114. In the current embodiment, the reactor channel 1400 includes a fluid entry section 1410 that include an inlet area 1412 for receiving the fluid. As the fluid passes through the inlet area 1412, it exits the inlet area (via exit point 1413) and flows down towards reactor channel opening 1414. When the fluid exits the inlet area 1412, fluid flowing or moving out of the reactor channel opening 1414 that is closer to the exit point 1413 (seen as area 1414a) has a higher velocity than the velocity of the fluid flowing or moving out of the reactor channel opening 1414 that is farther away from the exit point (seen as arear 1414b).

FIG. 14B shows Computational Fluid Dynamics (CFD) simulation of the flow through a reactor channel opening of a modular component with the reactor channel geometry shown in FIG. 14A. In the current embodiment, one end of the reactor channel opening delivers more precursor gas with a higher exit velocity than the opposite end of the reactor channel opening. When the reactor channel 1400 is used in a modular reactor head for CVD, this may result in more mixing of the precursor gases at one end of the precursor gas slit or opening, resulting in a non-uniform deposition rate along the length of the precursor gas slit. Alternatively, if the reactor channel 1400 is used in a modular reactor head for AP-SALD, at one end of the reactor channel opening the substrate may be fully saturated by the precursor during each ALD cycle while at the other end of the reactor channel opening, the substrate may not be fully saturated, again resulting in a non-uniform deposition rate along the length of the reactor channel opening. The geometry of the reactor channel opening may be varied for one or more reactor channel openings, resulting in a non-uniform deposition rate for one or more components of the film. If all film components have the same non-uniform deposition rate, a film with a non-uniform thickness in the first direction will result. In other words, the thickness of the film may vary. If film components with uniform and non-uniform deposition rates (or different non-uniform deposition rates) are deposited simultaneously, the resulting film will have a non-uniform composition.

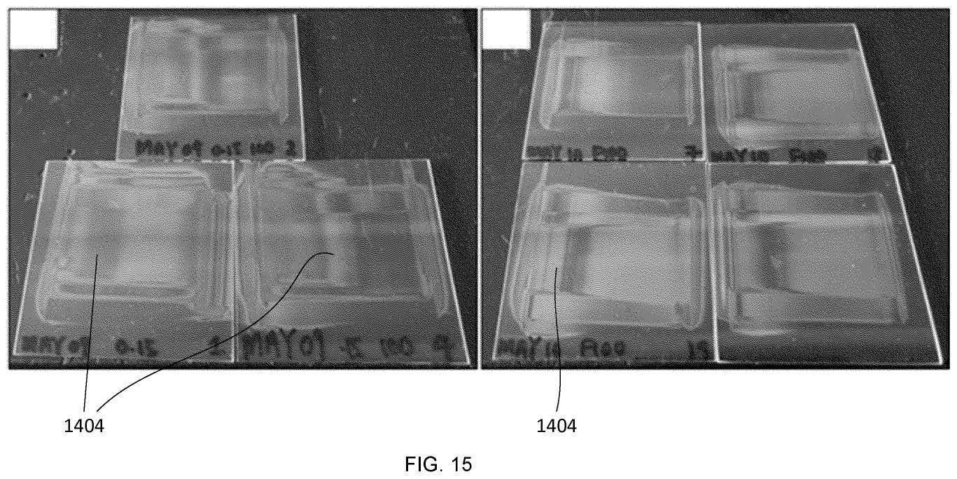

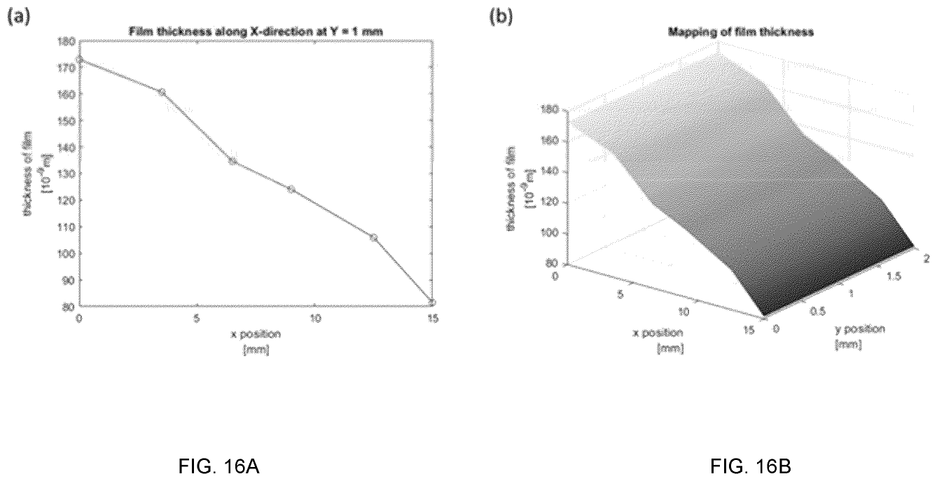

FIG. 14C is a schematic view of a reactor head 1402 having a non-uniform flow profile. FIG. 14D is a photograph of a 3D print of the reactor head 1402. In the present embodiment, all precursor gas reactor channel openings, inert gas reactor channel openings, and exhaust reactor channel openings (or precursor gas modular components, inert gas modular components, and exhaust modular components) are incorporated into a single reactor head component for small-scale testing. In alternative embodiments, the reactor head may include a plurality of modular components having a non-uniform flow profile. For the current embodiment, the reactor head 1402 was used to deliver diethylzinc with a non-uniform flow profile and water with a uniform flow profile to the surface of the substrate where they react to form zinc oxide (ZnO). Chemical vapor deposition (CVD) conditions were used, such that the delivery of more diethylzinc to one side of the substrate resulted in a higher deposition rate and a non-uniform film thickness. FIG. 15 is a photograph of examples of the zinc oxide films with thickness gradients produced using the reactor head 1402 and deposited using different precursor gas flow rates. A film thickness gradient is clearly visible from bands 1404 that form an interference pattern. FIG. 16A shows measurements of the film thickness across the substrate for a thickness gradient film from FIG. 15. FIG. 16B shows a map of film thickness over the surface of the same substrate. The reactor head 1402 may be used to simultaneously deliver another film component with a uniform flow profile, resulting in a film with a composition gradient in the first direction. A non-exclusive example of another film component is trimethylaluminum, which may react with water to form aluminum oxide, in which case the amount of zinc in the resulting aluminum-zinc-oxide alloy film would vary across the film or substrate.

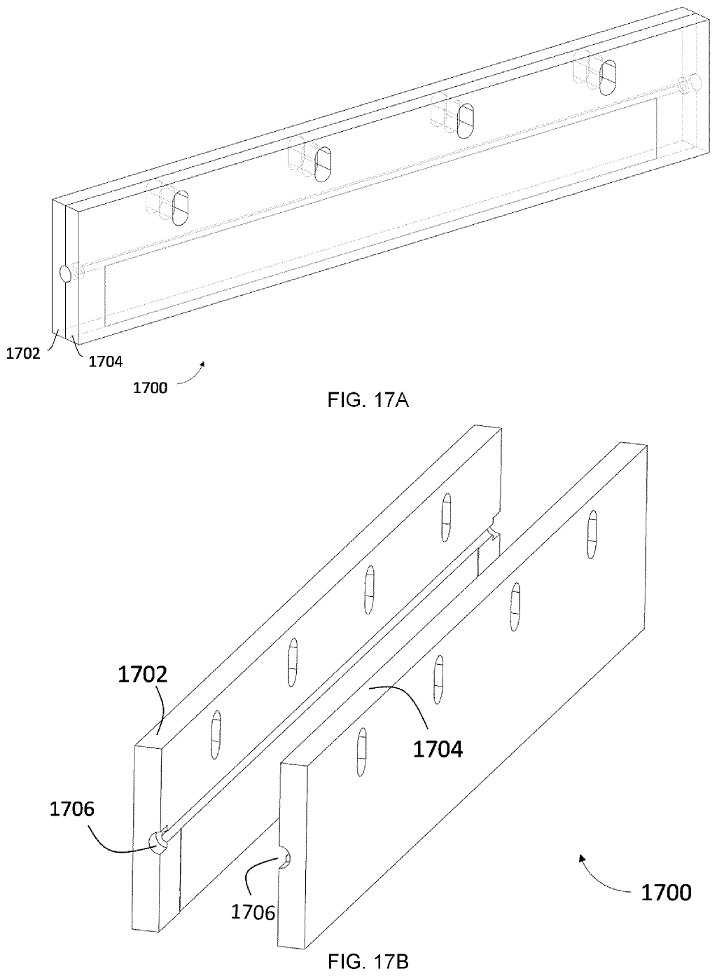

FIG. 17A shows a schematic view of an embodiment of a modular component 1700 that includes two symmetrical half-pieces 1702 and 1704. FIG. 17B shows an exploded perspective view of the modular component 1700. Each half-piece 1702 and 1704 has a relief portion 1706 having a uniform depth, where each relief portion 1706 of each half-piece 1702 and 1704 is positioned to form a reactor channel when the two half-pieces 1702 and 1704 are combined. The two symmetrical half-pieces 1702 and 1704 may be used to simplify the design for manufacturing a modular component by using additive manufacturing or mechanical machining and enabling low-cost fabrication of modular components having non-uniform flow profiles. The two symmetrical half-pieces 1702 and 1704 may be combined to form the modular component 1700 having a reactor channel with uniform width to deliver a uniform flow profile. Alternatively, the depth of each relief portion 1706 may be modified with additive manufacturing or mechanical machining to provide a non-uniform depth (or other contours) for each relief portion 1706 such that, when the two half-portions 1702 and 1704 are combined, a reactor channel with non-uniform flow is formed. With this fabrication technique, combined with the modular reactor head technology, each individual reactor head component can be easily customized, installed or swapped out, for different functions and purposes—for example, to enable deposition of films with thickness or composition gradients for fast prototyping or different functionalities.

Although not necessary in every embodiment, the thin film, or thin layer, deposition system of the disclosure may include a substrate positioning system that controls the position of the substrate held by the substrate stage relative to the modular reactor head. For example, the substrate positioning system may be a linear motor positioning system that oscillates the substrate held by the substrate stage and thereby enables high-throughput and high precision deposition. The linear motor based substrate positioning system may maintain the top surface of a substrate at a uniform height during motion, which enables accurate control of the space between the modular reactor head and a substrate when combined with the reactor positioning system.

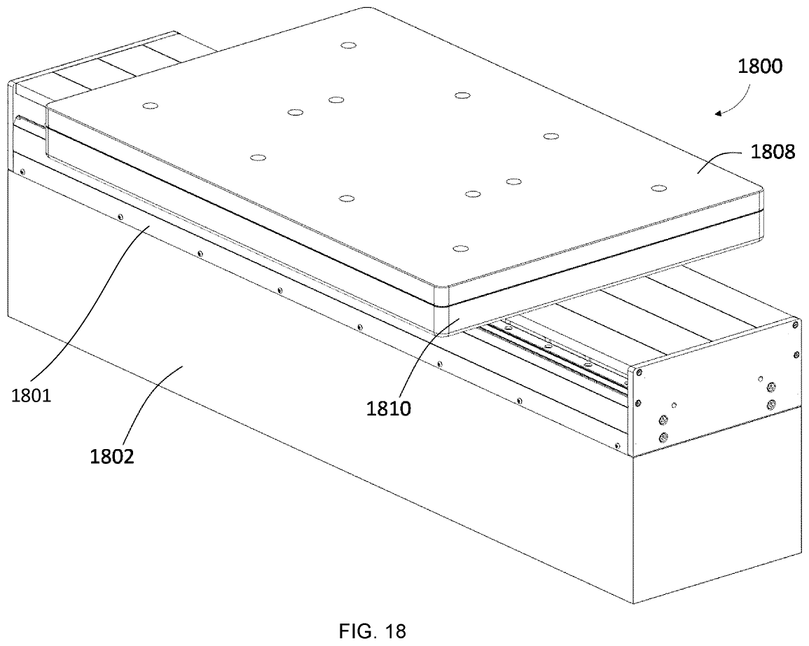

FIG. 18 is a perspective view of an embodiment of a substrate stage 1800 mounted on a linear motor system 1801 located atop a heavy mass, such as a granite slab 1802 to oscillate the substrate stage 1800 and substrate(s) underneath the modular reactor head. The substrate stage 1800 and substrate may be substantively similar to the substrate stage 108 and the substrate 106. In one specific embodiment, the substrate stage 1800, including an upper plate 1808 and vacuum reservoir 1810, is attached to the linear motor system 1801, which is mounted on a polished granite slab to absorb vibrations caused by the motion of the moving stage. In alternative embodiments, the linear motor system 1801 may be mounted on surfaces having a large mass and a high degree of flatness.

The linear motor positioning system 1801 may also enable non-uniform film deposition by oscillating the substrate stage 1800 and substrate with varying travel distances. The oscillating approach allows this technology to make thickness and composition gradients in the direction of substrate oscillation (direction 128 from FIG. 2). In other words, by varying the travel distance during oscillation, at least one of a thickness and a composition of the film may vary in this direction.

Overall, the thin film deposition system of the present disclosure may deposit a film where a composition or thickness gradient may be produced across the width of the film using precursor gas reactor channel openings that have customized geometries. A different thickness or composition gradient may be produced across the width of the film by varying the travel pattern of the heated substrate stage.

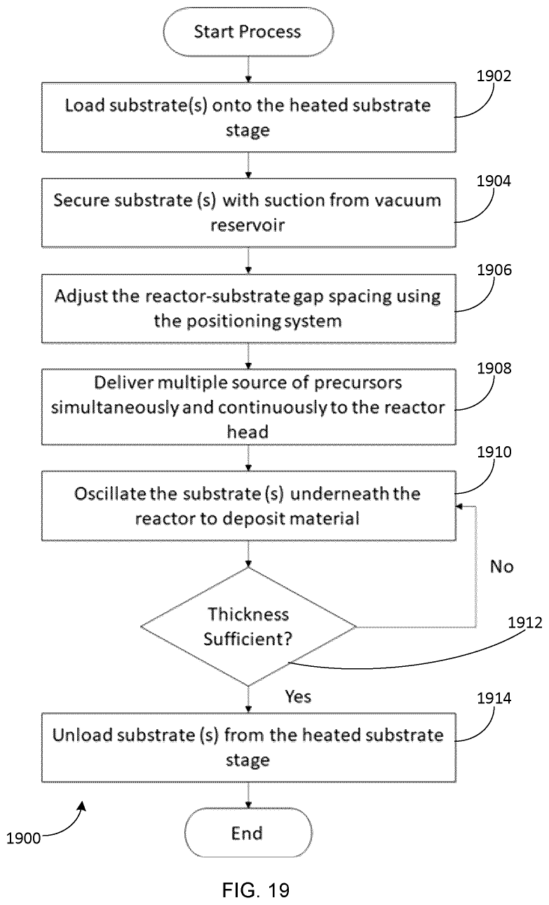

FIG. 19 shows a flow diagram for a method 1900 for depositing a thin film with a modular reactor head.

At 1902, a substrate is loaded onto a substrate stage. The substrate stage may be part of a thin film deposition system. The substrate stage may include a vacuum reservoir and a plurality of holes. At 1904, the substrate is secured to the substrate stage with suction from the vacuum reservoir. The suction may be provided to the substrate via the plurality of holes.

At 1906, a gap between the modular reactor head and the substrate is adjusted using the reactor head positioning system. The reactor head positioning system may be part of a thin film deposition system. Adjusting the gap includes controlling a distance between the modular reactor head and the substrate.

At 1908, multiple precursors, including precursor gases, are delivered simultaneously and continuously to the modular reactor head. The multiple precursor gases pass through the modular reactor head by passing through a respective reactor channel and out a respective reactor channel opening oriented towards the substrate. The position at which each precursor gas contacts the substrate is determined by the position of each respective precursor gas modular component within the modular reactor head.

At 1910, the substrate is oscillated underneath the modular reactor head and material is deposited by the modular components onto the substrate and thereby form a film. The substrate may be oscillated with a substrate positioning system. The substrate positioning system may be part of a thin film deposition system.

At 1912, if the thickness of the deposited film is not sufficient, the method returns to 1910. If the thickness of the film is sufficient, then at 1914 the substrate is removed from the substrate stage.

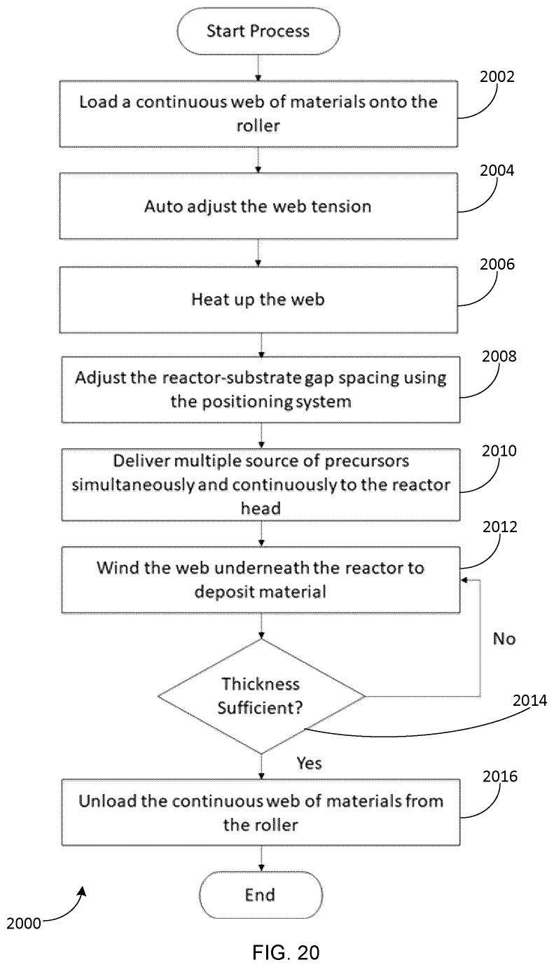

FIG. 20 shows a flow diagram for a roll-to-roll method 2000 for depositing a thin film with a modular reactor head.

At 2002, a continuous web of substrate wound around a first roll is loaded onto a first roller and coupled to a second roll mounted on a second roller.

At 2004, the tension of the substrate between the first roller and the second roller is adjusted automatically. At 2006, the temperature of the substrate is adjusted. Temperature adjustment may include heating the substrate.

At 2008, a gap between the modular reactor head and the substrate is adjusted using the reactor head positioning system. The reactor head positioning system may be part of a thin film deposition system. Adjusting the gap includes controlling a distance between the modular reactor head and the substrate.

At 2010, multiple precursors, including precursor gases, are delivered simultaneously and continuously to the modular reactor head. The multiple precursor gases pass through the modular reactor head by passing through a respective reactor channel and out a respective reactor channel opening oriented towards the substrate. The position at which each precursor gas contacts the substrate is determined by the position of each respective precursor gas modular component within the modular reactor head.

At 2012, the substrate is wound underneath the modular reactor head and material (such as the precursor gases) are deposited on the substrate and thereby form a film. If the substrate is wound around the first roll, the substrate may be wound underneath the modular reactor head by winding the substrate from the first roll to the second roll. If the substrate is wound around the second roll, the substrate may be wound underneath the modular reactor head by winding the substrate from the second roll to the first roll.

At 2014, if the thickness of the deposited film is not sufficient, the method returns to 2012. If the thickness of the film is sufficient, then at 2016 the web of substrate is unloaded.

In some embodiments, the disclosure may be directed at a modular reactor head that can be equipped with different components (heating channels, cooling channels, plasma sources, etc.) and whose components can be arranged and positioned in a variety of configurations such as, but not limited to a reactor head with modular components and adjustable positions and heights for each component that provides the ability to control gas flows and switch between ALD and CVD system configurations; a cooling/heating channel to control the temperature of the adjacent precursor gas slit to obtain desired thin film deposition conditions; a plasma source; and/or a scalable reactor slits that can increase the throughput of deposition.

In another embodiment, the disclosure may be directed at a system for positioning a reactor head relative to the substrate(s). The reactor head may be modular or non-modular. The system may further control the spacing between the reactor head and substrate and hence allows switching between ALD and CVD modes

In another embodiment, the disclosure may be directed at a heating substrate stage with suction and/or localized temperature control. In one embodiment, the heating substrate stage may include a vacuum holding mechanism capable of holding any substrate geometries and thicknesses. In another embodiment, the heating substrate stage may include thermal insulation of the heated substrate stage from other system components.

In another embodiment, the disclosure may be directed at customizable precursor gas slit designs that can produce uniform or non-uniform flow profiles from the slits that enables the deposition of films with non-uniform thickness and/or composition perpendicular to the direction of substrate motion

In a further embodiment, the disclosure may be directed at a linear motor positioning system that oscillates the substrate(s) relative to the modular reactor head that a) dampens vibrations and maintains substrate(s) at a uniform height during their oscillation to allow accurate control of the spacing between the substrate(s) and modular reactor head; and/or b) enables the deposition of films with non-uniform thickness and/or composition in the direction of the substrate motion. This can be combined with the customizable precursor gas slit designs to produce films with different thickness and composition gradients in orthogonal directions.

In yet a further embodiment, the disclosure may be directed at multiple deposition systems can be equipped with roll-to-roll technologies and/or substrate loading and unloading mechanisms for high-throughput production.

In another embodiment, the disclosure may be directed at depositing a thin layer of material on a fabric with the modular reactor head, for example ALD of copper oxide to a non-woven fabric for a N95 mask. Conventional spray coating or wet coating of copper oxide to a fabric typically fills in the pores of the fabric which may affect the performance of the mask, however CVD and/or ALD of copper oxide may provide an antiviral coating to the mask with a reduced effect on mask performance relative to conventional coating techniques.

Although the present disclosure has been illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present disclosure.

In the preceding description, for purposes of explanation, numerous details are set forth in order to provide a thorough understanding of the embodiments. However, it will be apparent to one skilled in the art that these specific details may not be required. In other instances, well-known structures may be shown in block diagram form in order not to obscure the understanding. For example, specific details are not provided as to whether elements of the embodiments described herein are implemented as a software routine, hardware circuit, firmware, or a combination thereof.

1. A modular reactor head for use with a thin film deposition system comprising:
a set of modular components, the set of module components adjacent each other in a first direction within the reactor head;
wherein the set of modular components may be positioned relative to each other in a second direction, the second direction substantially perpendicular to the first direction;
wherein the set of modular components include at least one precursor gas modular component for depositing at least two precursor gases onto a substrate.

2. The modular reactor head of claim 1 wherein the set of modular components comprises at least two precursor gas modular components.

3. The modular reactor head of claim 2 wherein the at least two precursor gas modular components are separated by at least one other modular component.

4. The modular reactor head of claim 1 wherein at least one of the set of modular components comprises:
a reactor channel; and
a reactor channel opening.

5. The modular reactor head of claim 4 wherein the reactor channel opening delivers a gaseous or liquid material with a higher exit velocity at one end of the reactor channel opening than at an opposite end of the reactor channel opening.

6. The modular reactor head of claim 1 wherein the set of modular components comprises at least one of a precursor fluid component, an exhaust modular component, an inert gas modular component, a temperature control modular component, chemical modular component, a cleaning modular component and a plasma source modular component.

7. The modular reactor head of claim 6 wherein the temperature control modular component comprises:
a metal plate for controlling a temperature of a modular component adjacent the temperature control modular component.

8. The modular reactor head of claim 7 wherein the temperature control modular component comprises a reactor channel for either receiving a cooling liquid to cool the metal plate or a heating liquid to heat the metal plate.

9. The modular reactor head of claim 1 wherein the set of modular components are mounted at predetermined heights with respect to each other.

10. A thin film deposition system comprising:
a substrate stage for supporting a substrate;
a modular reactor head for depositing thin films onto the substrate, the modular reactor head including a set of modular components, the set of module components adjacent each other in a first direction within the reactor head;
wherein the set of modular components may be positioned relative to each other in a second direction, the second direction substantially perpendicular to the first direction;
wherein the set of modular components include at least one precursor gas modular component for depositing at least two precursor gases onto a substrate; and
a modular reactor head position system for positioning the modular reactor head with respect to the substrate on the substrate stage.

11. The thin film deposition system of claim 10 wherein the modular reactor head position system comprises a linear displacement system.

12. The thin film deposition system of claim 11 wherein the linear displacement system comprises:
a set of displacement measuring devices; and
a set of linear actuators.

13. The thin film deposition system of claim 10 wherein the modular reactor head position system comprises:
a leveling system for gap control between the modular reactor head and the substrate stage.

14. The thin film deposition system of claim 10 wherein the substrate stage comprises:
a vacuum system for holding the substrate against the substrate stage.

15. The thin film deposition system of claim 10 wherein the substrate stage comprises:
an upper plate for supporting the substrate; and
a heating component for heating the upper plate.

16. The thin film deposition system of claim 10 wherein the substrate stage comprises a linear motor system.

17. The modular reactor head of claim 6 wherein the precursor fluid modular component comprises actuators to control precursor fluid deposition.
